(19) United States
(12) Patent Application Publication
(10) Pub. No.: US 2005/0241579 A1
(43) Pub. Date: Nov. 3, 2005

(54) Face shield to improve uniformity of blanket CVD processes

(76) Inventor: Russell Kidd, Hayward, CA (US)

Correspondence Address: MOSER, PATTERSON & SHERIDAN, LLP;APPLIED MATERIALS, INC., 3040 POST OAK BOULEVARD, SUITE 1500, HOUSTON, TX, 77056, US

(21) Appl. No.: 10/837,545

(22) Filed: Apr. 30, 2004

(51) Int. Cl. C23C 16/00

(52) U.S. Cl. 118/715; 427/248.1

(57) ABSTRACT

A gas delivery assembly for uniform gas flow within a processing system is provided. In one aspect, a gas delivery assembly includes sidewalls at least partially disposed about a gas delivery component disposed within the processing system. The gas delivery shield also includes a bottom wall having a varied profile that extends beyond the gas delivery component to define a varied spacing above the substrate. The bottom wall of the gas delivery also includes a plurality of gas passageways formed therethrough to deliver a uniform gas distribution to a substrate being processed.

### BACKGROUND OF THE INVENTION

1. Field of the Invention

Embodiments of the present invention generally relate to a gas distribution system utilized in semiconductor processing equipment, and more particularly to a gas distribution system having a protective face shield for use in chemical vapor deposition (CVD) and dry etch chambers.

2. Description of the Related Art

Gas distribution plates or showerheads are commonly used to uniformly distribute deposition and etch gases into a processing chamber. Such a uniform gas distribution is necessary to achieve uniform deposition or uniform etch characteristics on the surface of a substrate as well as necessary to achieve reproducibility and reliability. Due to harsh processing conditions within the chamber, uniform gas distribution is hard to achieve and sometimes more difficult to repeat.

It is believed that the problems associated with distribution non-uniformity are at least partially dependent on the flow of gases across the surface of the substrate being processed. Gases tend to flow along the path of least resistance which is most often toward the center of the substrate, which is directly aligned with the gas inlet. Another prominent flow path is about the periphery of the substrate due to the pull from the attached vacuum system. Therefore, the amount of etch and deposition is often not uniform across the face of the substrate.

Another problem associated with distribution non-uniformity is the progressive erosion of the various components making up the gas delivery system. Erosion is an inevitable result of processing and is compounded after performing multiple processes within the same chamber. The erosion may be a result of arcing during a plasma enhanced process as well as a result of a chemical reaction with the process gases during a process. Because the dimensions of the various components making up the gas delivery system affect the plasma density and the distribution of process gases across the substrate, this progressive erosion changes the characteristics of the performed process. Therefore, maintaining process consistency and uniformity generally requires the prevention or control of erosion and ultimately, requires periodic replacement of the eroded components. As expected, replacement of eroded components consumes valuable processing time, which relates to lost profits.

There is a need, therefore, for a gas delivery system that is capable of delivering a uniform gas flow and one that can prevent or control erosion. There is also a need for a gas delivery system that reduces processing downtime by decreasing the frequency of scheduled maintenance and component replacement.

### SUMMARY OF THE INVENTION

The present invention generally provides a gas delivery shield for a semiconductor processing system. In one aspect, the gas delivery shield includes sidewalls at least partially disposed about a gas delivery component disposed within the processing system. The gas delivery shield also includes a bottom wall within the sidewalls having a varied profile that extends beyond the gas delivery component to define a varied spacing above the substrate. The lower surface of the gas delivery also includes a plurality of gas passageways formed therethrough to deliver a controlled and uniform distribution of gas.

A gas delivery assembly for semiconductor processing is also provided. In one aspect, the gas delivery assembly includes a face shield and a showerhead having a plurality of gas passageways formed therethrough. The face shield includes sidewalls at least partially disposed about the showerhead. The face shield also includes a bottom wall within the sidewalls having a varied profile that extends beyond the gas delivery component to define a spacing above the substrate. The bottom wall of the face shield includes a plurality of gas passageways formed therethrough.

A substrate processing chamber is also provided. In one aspect, the substrate processing chamber includes a chamber body having a support member disposed therein. The support member includes an upper surface adapted to support a substrate to be processed. The substrate processing chamber also includes a gas delivery assembly disposed above the support member which is adapted to deliver one or more gases into the chamber body. The gas delivery assembly includes a face shield and a showerhead having a plurality of gas passageways formed therethrough. The face shield includes sidewalls disposed about the showerhead, and a bottom wall within the sidewalls having a varied profile that extends beyond the gas delivery component to define a spacing above the substrate. The bottom wall of the face shield also includes a plurality of gas passageways formed therethrough.

Furthermore, a method for processing a substrate is provided. In one aspect, the method comprises positioning a substrate within a processing chamber, delivering one or more gases through a gas delivery assembly and depositing one or more materials on the substrate surface. The gas delivery assembly includes a face shield and a showerhead having a plurality of gas passageways formed therethrough. The face shield includes sidewalls disposed about the showerhead, and a bottom wall within the sidewalls having a varied profile that extends beyond the gas delivery component to define a spacing above the substrate. The bottom wall of the face shield also includes a plurality of gas passageways formed therethrough.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments. To facilitate understanding, similar reference numerals have been used, wherever possible, to designate elements that are common to the figures.

FIG. 1 is a partial cross section view of a typical semiconductor processing chamber having a face shield disposed therein.

FIG. 2 is an enlarged schematic view of the gas delivery assembly shown in FIG. 1.

FIGS. 3A and 3B show one embodiment of the face shield affixed to the gas delivery assembly using a threaded connection.

FIGS. 4A and 4B show another embodiment of the face shield affixed to the gas delivery assembly using a fastening member.

FIG. 5 is a schematic plan view of the face shield according to one embodiment described herein.

FIG. 6 is a partial cross section view of an exemplary multiple wafer processing system utilizing the face shield described herein.

FIG. 7 is a cross section view of a tandem processing chamber shown in FIG. 6.

### DETAILED DESCRIPTION OF THE PREFERRED EMBODIMENT

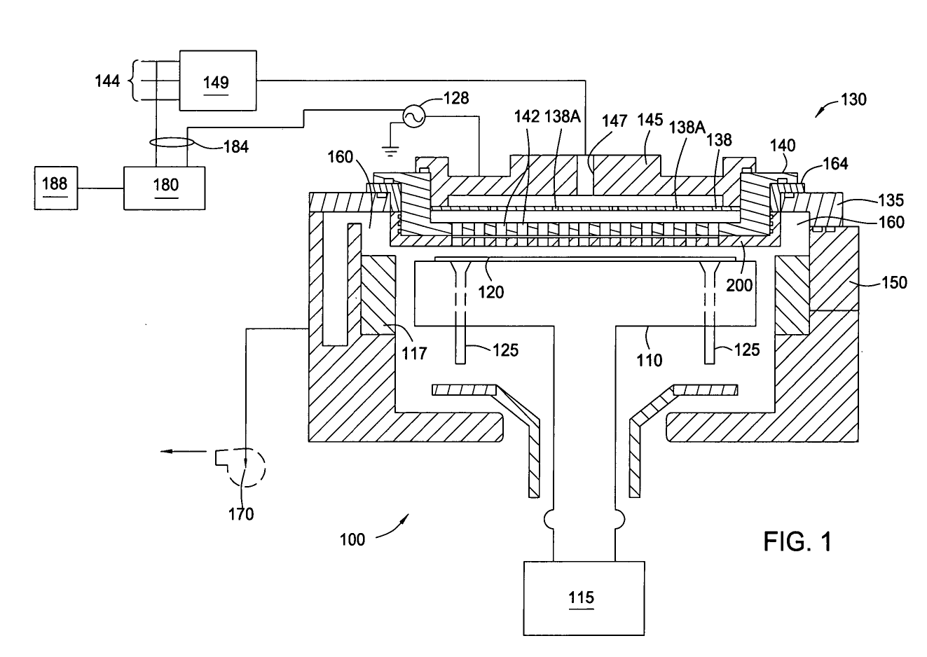

A gas delivery system having a protective face shield to reduce erosion of the showerhead and to improve the uniformity of gas distribution within a processing chamber is provided. FIG. 1 shows a partial cross section view of a typical semiconductor processing chamber 100 utilizing a face shield 200 according to embodiments described herein. The illustrated chamber 100 is a plasma enhanced chamber suitable for etching or chemical vapor deposition (CVD), and is commercially known as a DxZ Chamber® from Applied Materials, Inc., of Santa Clara, Calif.

In one embodiment, the chamber 100 includes a support member 110 having an upper surface on which a substrate 120 is supported for processing. The support member 110 can be controllably moved by a lift motor 115 between a lower position for transferring a substrate in and out of the chamber 100, and an elevated position for processing within the chamber 100. The chamber 100 may also include vertically movable lift pins 125 to facilitate transfer of the substrate 120. An insulator or liner 117 surrounds the support member 110 and the substrate 120 when in an upper processing position.

A gas delivery assembly 130 is disposed on a lid rim 135 at an upper end of the chamber body 150. The gas delivery assembly 130 includes one or more components stacked one on top of another. A typical gas delivery assembly 130, for example, includes a blocker plate 138, a gas distribution faceplate 140 often referred to as a showerhead, and a gas-feed cover plate or temperature control plate 145. The gas-feed cover plate 145 is disposed on the faceplate 140 and in thermal communication therewith. The gas feed cover plate 145 includes a central gas inlet 147 which is coupled to one or more upstream gas sources 144 and/or other gas delivery components, such as a gas mixer 149 described in more detail below. The term “gas” as used herein refers to one or more precursors, reactants, catalysts, carrier, purge, etch, cleaning, combinations thereof, as well as any other fluid introduced into the chamber 100.

The blocker plate 138 includes a plurality of passageways 138A formed therein that are adapted to disperse the gases flowing from the inlet 147 to the faceplate 140. Although the passageways 138A are shown as being circular or rounded, the passageways 138A may be square, rectangular, or any other shape. The passageways 138A are sized and positioned about the blocker plate 138 to provide a controlled and uniform flow distribution across the surface of the substrate 120.

The faceplate 140 includes a plurality of passageways 142 formed therein that are adapted to disperse the gases flowing from the blocker plate 138 to the chamber body 150. Like the holes 138A of the blocker plate 138, the passageways 142 may be circular or rounded. Additionally, the passageways 142 may be square, rectangular, or any other shape. Preferably, the passageways 142 are sized and positioned about the faceplate 140 to further assist in providing a controlled and uniform flow distribution across the surface of the substrate 120 disposed below.

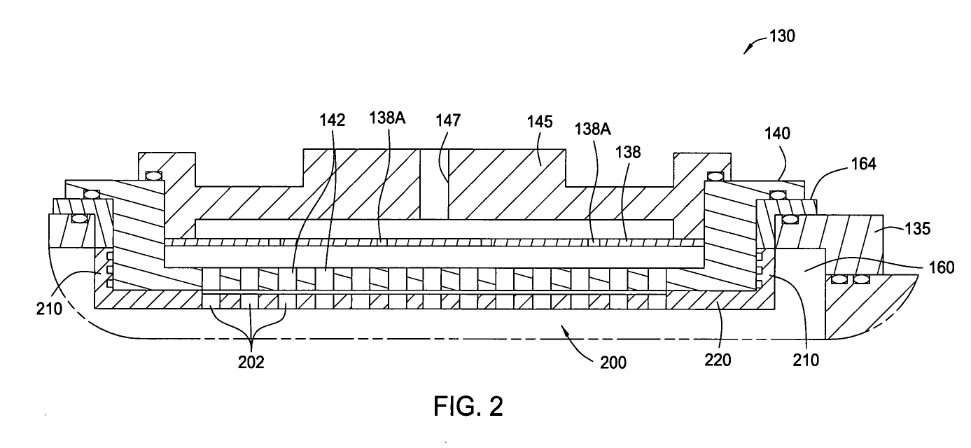

Referring to FIGS. 1 and 2, the face shield 200 is at least partially disposed about one or more components of the gas delivery assembly 130. FIG. 2 shows an enlarged schematic view of the gas delivery assembly 130 shown in FIG. 1. The face shield 200 is a replaceable part and may be constructed of any process compatible material, such as aluminum-6061 for example.

Preferably, the face shield 200 resembles the size and shape of the faceplate 140. The face shield includes sidewalls 210 and a bottom wall or plate 220 that is disposed within the sidewalls 210. The bottom wall 220 extends beyond a lower surface of the faceplate 140 to assist in providing a controlled and uniform flow of gases therethough. The bottom wall 220 may be circular, rounded, elliptical, squared or resemble any other shape. In one aspect, the bottom wall 220 may have a constant cross sectional thickness. In another aspect, the bottom wall 220 may have a variable cross sectional thickness such that the thickness of the bottom wall 200 increases or decreases or both increases and decreases from a center point thereof to an outer perimeter thereof. This variable thickness may be helpful in further assisting the flow of gases therethrough.

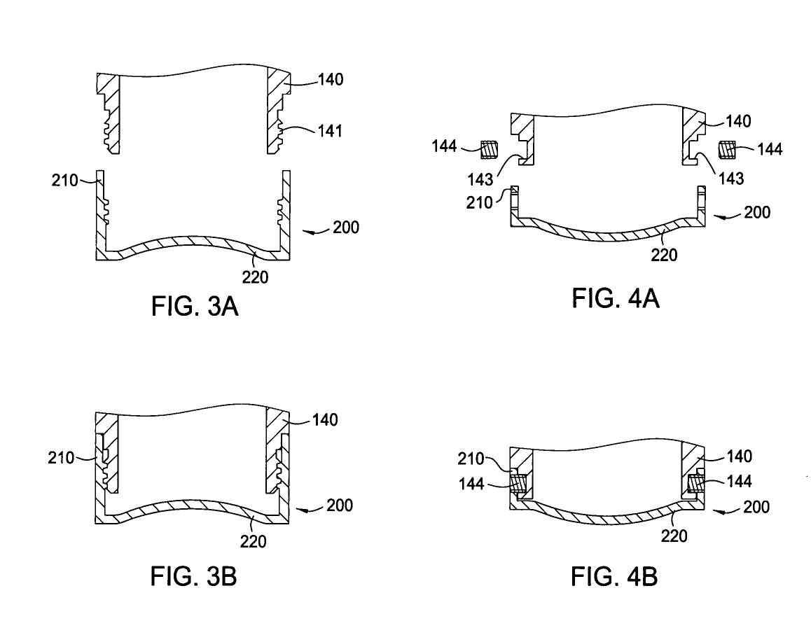

An outer diameter of the faceplate 140 may be threaded so that the face shield 200 can be screwed onto the outer diameter of the faceplate 140 as shown in FIGS. 3A and 3B. In this configuration, the sidewalls 210 of the face shield 200 include one or more threaded members that matingly engage the threaded outer diameter of the faceplate 140 so to make a threaded connection. Alternatively or in addition to the threads mentioned above, the face plate 140 may have one or more threaded holes or receptacles formed in an outer diameter thereof such that the sidewalls 210 of the face shield 200 can be affixed to an outer diameter of the faceplate 140 using a bolt, screw, or other fastening device, as shown in FIGS. 4A and 4B. In either embodiment, the face shield 200 is easily removable for cleaning or replacement after a period of use. The faceplate 140 is also easily accessible for similar maintenance or replacement once the face shield 200 is removed,

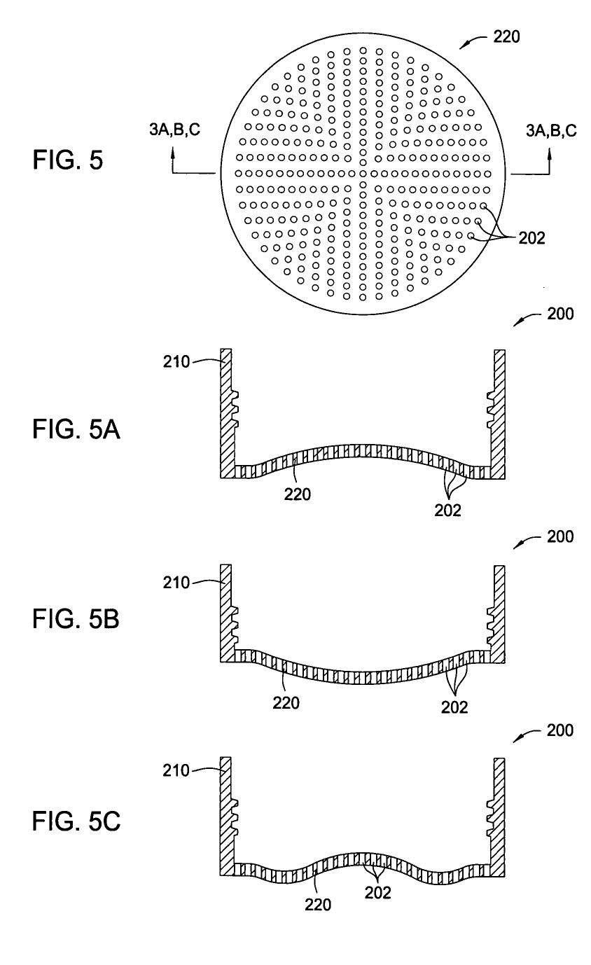

Considering the face shield 200 in more detail, FIG. 5 shows a schematic plan view thereof. As shown, the bottom wall 220 of the face shield 200 includes a plurality of holes or gas passageways 202 similar to the faceplate 140 so that the two components work together to provide an uniform gas flow and gas distribution across the surface of the substrate 120 to be processed. Any arrangement or configuration of the holes 202 may be used. As such, the face shield 200 serves as an extension of the faceplate 140, and provides protection for the faceplate 140 against the harsh processing environment within the chamber body 150.

The bottom wall 220 of the face shield 200 has a variable profile to vary or manipulate the distribution of gas exiting the gas delivery assembly 130. It has been observed that the greater the distance or the amount of spacing between the substrate 120 and the gas delivery assembly 130, the greater the rate of deposition, and the greater the rate of etch. Similarly, a shorter spacing provides a slower rate of deposition and a slower rate of etch. As such, the rate of deposition and the rate of etch across the surface of the substrate 120 can be controlled or manipulated by the spacing between the face shield 200 extended from the gas delivery assembly 130 and the substrate surface 120.

FIGS. 5A-5C show cross section views of exemplary embodiments of the face shield 200 useful for manipulating the spacing between the face shield 200 extended from the gas delivery assembly 130 and the substrate 120. In one embodiment, the face shield 200 has a concave profile as shown in FIG. 5A. In this embodiment, a greater distance, i.e. greater amount of spacing, is formed between the substrate 120 and an inner portion of the face shield 200 and a shorter distance is created about the periphery of the substrate 120. As a result, faster deposition at the inner portion of the substrate 120 is achieved due to the increased volume of gases above the inner portion of the substrate. Likewise, slower deposition at the periphery of the substrate 120 is achieved due to the smaller volume of gases above that portion of the substrate 120. Therefore, in the same amount of time, more deposition occurs at the inner portion of the substrate 120 having a greater spacing compared to the periphery of the substrate 120 having a shorter spacing.

In another embodiment, the face shield 200 has a convex profile as shown in FIG. 5B. In this embodiment, a shorter distance is formed between the inner portion of substrate 120 and an inner portion of the face shield 200. As such, faster deposition at the perimeter of the substrate is achieved due to the increased volume of gases above the peripheral edges of the substrate 120.

In yet another embodiment, the face shield 140 may have a wavy or alternating profile as shown in FIG. 5C. In this embodiment, the distance between the substrate 120 and the face shield 200 varies across the surface of the substrate 200. Therefore, different rates of deposition can be achieved at different locations on the substrate surface.

These various configurations of the face shield 200 are merely exemplary and not intended to be an exhaustive list of alternatives. The idea is to vary the spacing between the upper surface of the substrate 120 and the lower surface of the face shield 200 to control or enhance deposition and etch uniformity on the substrate 120 being processed. It is believed that this uniformity is directly influenced by the volume of gases directly above the substrate surface. By controlling this spacing, a greater gas volume can be manipulated above various discrete locations on the substrate 120 such that greater deposition or etch occurs where the spacing in greater. Likewise, a smaller volume of gases can be manipulated above various discrete locations of the substrate surface such that less deposition or etch occurs where the spacing is less. In other words, it is believed that the spacing has a direct, linear relationship to the rate of deposition and the rate of etch on the substrate surface. As such, the rate of deposition can be controlled at various discrete portions of the substrate surface by manipulating the spacing between the face shield 200 and the substrate 120.

In addition to controlling the rate of deposition and etch at various locations of the substrate surface, the face shield 200 is useful for protecting the more costly components of the gas distribution assembly 130 from damage, namely the faceplate 140. For example, damage to the faceplate 140 may be caused during deposition processes by arcing. Also, the faceplate 140 is often damaged during etch processes due to the corrosive nature of the etchant chemicals. The face shield 200 will surround and therefore, protect the faceplate 140 from these types of damages. As such, the face shield 200 is exposed to these damaging circumstances instead of the faceplate 140. Since the face shield 200 is less costly to replace than the faceplate 140, the cost of ownership of the chamber 100 is greatly reduced.

In addition to assisting in gas delivery into the chamber body 150, the faceplate 140 also acts as an electrode. During processing, a power source 128 supplies power to the faceplate 140 to facilitate the generation of a plasma. Any power source capable of activating the gases into reactive species and maintaining the plasma of reactive species may be used. For example, radio frequency (RF), direct current (DC), or microwave (MW) based power discharge techniques may be used. The activation may also be generated by a thermally based technique, a gas breakdown technique, a high intensity light source (e.g., UV energy), or exposure to an x-ray source. Alternatively, a remote activation source may be used, such as a remote plasma generator, to generate a plasma of reactive species which are then delivered into the chamber 100. Exemplary remote plasma generators are available from vendors such as MKS Instruments, Inc. and Advanced Energy Industries, Inc. Preferably, a RF power supply is coupled to the electrode 240.

In one embodiment, the power source 128 supplies either a single frequency RF power between about 0.01 MHz and 300 MHz or mixed simultaneous frequencies to enhance decomposition of reactive species introduced into the chamber 100. In one aspect, the mixed frequency is a lower frequency of about 12 kHz and a higher frequency of about 13.56 mHz. In another aspect, the lower frequency may range between about 300 Hz to about 1,000 kHz, and the higher frequency may range between about 5 mHz and about 50 mHz.

A system controller 180 controls the lift motor 115, the gas mixing system 149, and the power supply 128 which are connected therewith by control lines 184. The system controller 180 controls the activities of the chamber 100 and typically includes a hard disk drive, a floppy disk drive, and a card rack collectively represented by module 188. The card rack contains a single board computer (SBC), analog and digital input/output boards, interface boards, and stepper motor controller boards. The system controller 180 conforms to the Versa Modular Europeans (VME) standard which defines board, card cage, and connector dimensions and types. The VME standard also defines the bus structure having a 16-bit data bus and 24-bit address bus.

In operation, a substrate 120 is positioned on the pedestal 110 through cooperation of a robot (not shown) and the lift pins 125. The pedestal 110 then raises the substrate into close opposition to the gas delivery assembly 130. Process gas is then injected into the chamber 100 through the gas-feed cover plate 145 via the inlet 147 to the back of the faceplate 140. The process gas then passes through the holes 138A of the blocker plate 138, the holes 142 of the faceplate 140, the holes 202 of the face shield 200, and into the chamber body 150. Subsequently, the process gas byproducts flow radially outwardly across the edge of the substrate 120, into a pumping channel 160 and are then exhausted from the chamber 100 by a vacuum system 170.

An electronically operated valve and/or flow control mechanism (not shown) may be used to control the flow of gas from the gas supply 144 into the chamber 100. The gas is provided to the faceplate 140 by gas supply lines 144 in fluid communication with the gas-feed cover plate 145. One or more process gases and optional carrier gases are input through gas lines 144 into a mixing system 149 where the gases are combined and delivered to the gas delivery assembly 130. The gas delivery assembly 130 may be cooled or heated depending on the particular process requirements.

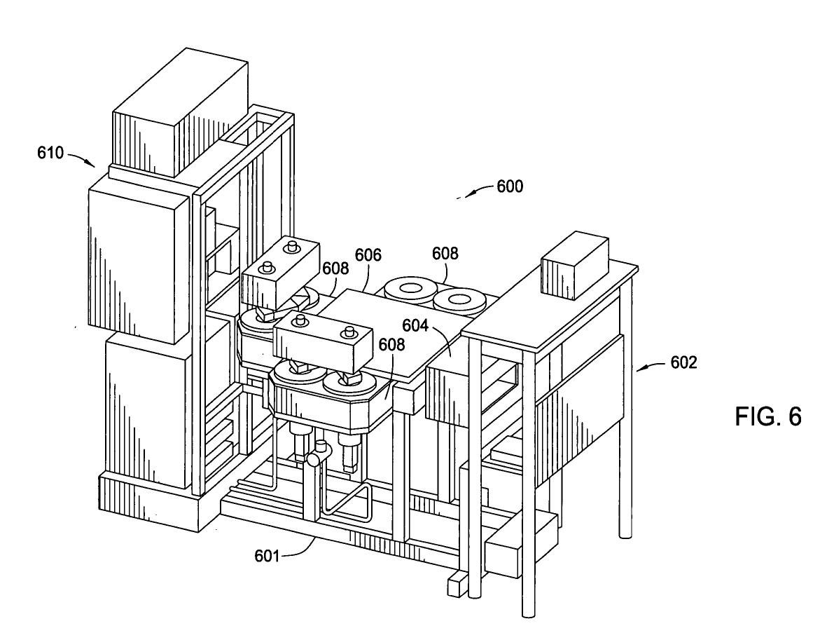

A processing chamber utilizing the face shield 200, such as the CVD chamber 100 described above, may be integrated into a multiple wafer processing system. FIG. 6 shows a partial cross section view of an exemplary multiple wafer processing system 600. Such a processing system 600 is known as the PRODUCER® which is commercially available from Applied Materials, Inc., located in Santa Clara, Calif. The system 600 provides a cassette-to-cassette vacuum processing system which concurrently processes multiple wafers and combines the advantages of single wafer process chambers and multiple wafer handling for high quality wafer processing, high wafer throughput and reduced system footprint.

The system 600 is a self-contained system having the necessary processing utilities supported on a mainframe structure 601. In one embodiment, the system 600 is a staged vacuum system which generally includes a front end staging area 602 where wafer cassettes (not shown) are supported and wafers are loaded into and unloaded from a loadlock chamber 604. The loadlock chamber 604 introduces substrates into the system 600 and also provides substrate cooling following processing. The system 600 also includes a transfer chamber 606 for housing a substrate handler, and one or more tandem processing chambers 608 mounted on the transfer chamber 606. Each processing chamber 608 can be outfitted to perform a number of substrate processing operations such as atomic layer deposition (ALD), cyclical layer deposition, chemical vapor deposition (CVD), physical vapor deposition (PVD), etch, pre-clean, degas, orientation and other substrate processes. The system 600 also includes a back end 610 which houses the support utilities needed for operation of the system 600, such as a gas panel, power distribution panel and power generators (not shown).

The tandem processing chambers 608 are configured to allow multiple, isolated processes to be performed concurrently in at least two regions so that at least two wafers can be processed simultaneously in separate processing regions with a high degree of process control. This configuration also benefits from shared gas sources, shared exhaust systems, separate gas distribution assemblies, separate RF power sources, and separate temperature control systems. An exemplary tandem processing chamber 608 is described in U.S. Pat. No. 5,855,681, which is incorporated by reference herein.

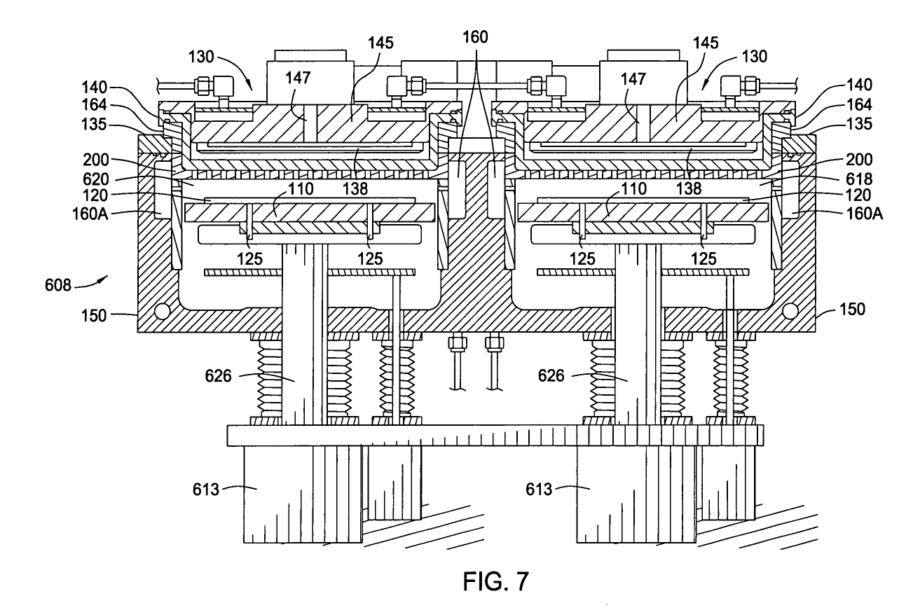

FIG. 7 shows a cross sectional view of such a tandem processing chamber 608 utilizing the face shield 200 described above. Generally, the chamber 608 has two processing regions 618 and 620 each contained within a chamber body 150A. The support members 110 are movably disposed within the processing regions 618, 620 by stems 626 that extend through the bottom of the chamber body 150A where it is connected to a drive system 613. Each processing region 618, 620 is in fluid communication with a gas distribution assembly 130 having a face shield 200 attached thereto as described above.

While the foregoing is directed to embodiments of the present invention, other and further embodiments of the invention may be devised without departing from the basic scope thereof, and the scope thereof is determined by the claims that follow.

1. A gas delivery shield for a semiconductor processing system, comprising:
sidewalls at least partially disposed about a gas delivery component disposed within the processing system; and
a bottom wall within the sidewalls having a plurality of gas passageways formed therethrough and a varied profile that extends beyond the gas delivery component to define a varied spacing above the substrate.

2. The shield of claim 1, wherein the sidewalls form a threaded connection with at least a portion of an outer perimeter of the gas delivery assembly.

3. The shield of claim 1, wherein the sidewalls are affixed to at least a portion of an outer perimeter of the gas delivery assembly using a bolt, screw, or other means for fastening.

4. The shield of claim 1, wherein the gas delivery assembly comprises one or more components selected from the group consisting of a blocker plate, a showerhead, a cover plate, and combinations thereof.

5. The shield of claim 1, wherein the gas delivery assembly comprises a blocker plate disposed on a showerhead, each comprising a plurality of gas passageways formed therethrough.

6. A gas delivery assembly for semiconductor processing, comprising:
a showerhead having a plurality of gas passageways formed therethrough; and
a face shield, comprising:
sidewalls at least partially disposed about the showerhead; and
a bottom wall within the sidewalls having a plurality of gas passageways formed therethrough and a varied profile that extends beyond the gas delivery component to define a varied spacing above the substrate.

7. The gas delivery assembly of claim 6, wherein the sidewalls form a threaded connection with at least a portion of an outer perimeter of the showerhead.

8. The gas delivery assembly of claim 6, wherein the sidewalls are affixed to at least a portion of an outer perimeter of the showerhead using a bolt, screw, or other means for fastening.

9. The gas delivery assembly of claim 6, further comprising one or more components selected from a group consisting of a blocker plate, a cover plate, and combinations thereof.

10. The gas delivery assembly of claim 6, further comprising a blocker plate disposed on the showerhead, the blocker plate comprising a plurality of gas passageways formed therethrough.

11. A substrate processing chamber, comprising:
a chamber body having a support member disposed therein, the support member having an upper surface adapted to support a substrate to be processed thereon;
a gas delivery assembly disposed above the support member adapted to deliver one or more gases into the chamber body, wherein the gas delivery assembly comprises:
a showerhead having a plurality of gas passageways formed therethrough; and
a face shield, comprising:
sidewalls disposed about the showerhead; and
a bottom wall within the sidewalls having a plurality of gas passageways formed therethrough and a varied profile that extends beyond the gas delivery component to define a varied spacing above the substrate.

12. The chamber of claim 11, wherein the sidewalls form a threaded connection with at least a portion of an outer perimeter of the showerhead.

13. The chamber of claim 11, wherein the sidewalls are affixed to at least a portion of an outer perimeter of the showerhead using a bolt, screw, or other means for fastening.

14. The chamber of claim 11, further comprising one or more components selected from a group consisting of a blocker plate, a cover plate, and combinations thereof.

15. The chamber of claim 11, further comprising a blocker plate disposed on the showerhead, the blocker plate comprising a plurality of gas passageways formed therethrough.

16. A method for processing a substrate, comprising:
positioning a substrate within a processing chamber;
delivering one or more gases through a gas delivery assembly comprising:
a showerhead having a plurality of gas passageways formed therethrough; and
a face shield, comprising:
sidewalls disposed about the showerhead; and
a bottom wall within the sidewalls having a plurality of gas passageways formed therethrough and a varied profile that extends beyond the gas delivery component to define a varied spacing above the substrate; and
depositing one or more materials on the substrate surface.
